(19) United States
(12) Patent Application Publication
(10) Pub. No.: US 2026/0258936 A1
(43) Pub. Date: Sep. 3, 2026

(54) LED BACKLIGHT SOURCE AND MANUFACTURING METHOD THEREFOR

(71) Applicant: FOSHAN NATIONSTAR OPTOELECTRONICS CO., LTD., Guangdong (CN)

(72) Inventors: Junhua CHEN, Guangdong (CN); Danlei GONG, Guangdong (CN); Zhonghai YAN, Guangdong (CN); Fabo LIU, Guangdong (CN); Hua FAN, Guangdong (CN); Guohong HUANG, Guangdong (CN); Yong YANG, Guangdong (CN); Youwei ZHAN, Guangdong (CN); Jianwen CHEN, Guangdong (CN); Taotao SONG, Guangdong (CN); Danwei LI, Guangdong (CN)

(21) Appl. No.: 18/718,157

(22) PCT Filed: Aug. 9, 2022
(86) PCT No.: PCT/CN2022/111092

§ 371 Date: Jun. 10, 2024

(30) Foreign Application Priority Data
Dec. 28, 2021 (CN) 202111630287.2

(51) Int. Cl. F21V 23/00; F21V 19/00

(52) U.S. Cl. CPC F21V 23/005; F21V 19/002

(57) ABSTRACT

An LED backlight source includes a substrate, an LED chip, and a driver IC. The substrate has a first side. LED chips and driver ICs are disposed at intervals on the first side, respectively. M partitions are disposed on the first side, one driver IC and N channels are disposed in each partition, and one driver IC controls X LED chips through one channel, where M, N, and X are integers greater than or equal to 1, N is less than or equal to 6, and the appearance of the driver IC is white.

This application claims priority to Chinese Patent Application No. 202111630287.2 filed with the China National Intellectual Property Administration (CNIPA) on Dec. 28, 2021, the disclosure of which is incorporated herein by reference in its entirety.

### TECHNICAL FIELD

The present application relates to the technical field of light-emitting diodes (LEDs), for example, an LED backlight source and a manufacturing method therefor.

### BACKGROUND

Currently, an LED backlight source generally adopts a structure of an integrated lamp driver where a driver unit and a light-emitting unit are on the same substrate. When the driver unit and the light-emitting unit are installed on the same side of the substrate, a driver integrated circuit (IC) using a black substrate absorbs or blocks light, which affects the optical effect of the backlight source. Generally, a driver IC used by the driver unit drives more than 32 channels, and the number of chips in each channel is relatively large. When the number of backlight source chips is large, the circuit layout becomes extremely complex, and the IC is relatively large due to the large number of channels driven by the IC. If the IC is disposed on the same side as the light-emitting unit, the light emission of the chips is blocked, and the maintenance cost is high.

### SUMMARY

Embodiments of the present application provide an LED backlight source with a simple structure, a small volume of a driver IC, a small number of channels, a simple circuit layout, and good display effects.

Embodiments of the present application provide a manufacturing method for an LED backlight source, which is easy to operate. The method can use a one-time solder paste printing process to meet the needs of different amounts of solder paste on the substrate.

Embodiments of the present application adopt technical solutions described below.

In a first aspect, an LED backlight source is provided. The LED backlight source includes a substrate, an LED chip, and a driver IC. The substrate has a first side. LED chips and driver ICs are disposed at intervals on the first side. M partitions are disposed on the first side, one driver IC and N channels are disposed in each partition, and one driver IC controls X LED chips through one channel, where M, N, and X are integers greater than or equal to 1, N is less than or equal to 6, and the appearance of the driver IC is white.

In a second aspect, a manufacturing method for an LED backlight source is provided, which is configured to manufacture the preceding LED backlight source. The method includes the steps below.

A substrate and a steel mesh are provided, the steel mesh is aligned with the substrate, and solder paste is simultaneously applied to an LED pad and an IC pad of the substrate through the steel mesh, where the amount of solder paste on the LED pad and the amount of solder paste on the IC pad are different.

An LED chip and a driver IC with a white appearance are provided, and the LED chip and the driver IC are soldered respectively on the LED pad and the IC pad using the reflow soldering to form the LED backlight source.

In a third aspect, a manufacturing method for an LED backlight source is provided. The method includes the steps below.

A substrate and a steel mesh are provided, the steel mesh is aligned with the substrate, and solder paste is simultaneously applied to an LED pad and an IC pad of the substrate through the steel mesh, where the amount of solder paste on the LED pad and the amount of solder paste on the IC pad are different.

An LED chip and a driver IC are provided, and the LED chip and the driver IC are soldered respectively on the LED pad and the IC pad using the reflow soldering to form the LED backlight source.

The driver IC is coated with white glue, and the LED backlight source with the driver IC is dried in an oven to make the appearance of the driver IC white.

### BRIEF DESCRIPTION OF DRAWINGS

FIG. 1 is a front view of an LED backlight source according to an embodiment of the present application.

FIG. 2 is a side view of an LED backlight source according to an embodiment of the present application.

FIG. 3 is a schematic diagram of the installation positions of an LED backlight source and optical components according to an embodiment of the present application.

FIG. 4 is a front view of an LED backlight source with a white glue-coated driver IC according to an embodiment of the present application.

FIG. 5 is a front view of an LED backlight source with a driver IC packaged with plastic packaging material according to an embodiment of the present application.

FIG. 6 is a front view of a partition on the substrate of an LED backlight source according to an embodiment of the present application.

FIG. 7 is a front view of a partition on the substrate of an LED backlight source according to another embodiment of the present application.

FIG. 8 is a sectional view of the cooperation between the substrate and the steel mesh in manufacturing an LED backlight source according to an embodiment of the present application.

### Reference List

1 substrate
11 first side
111 partition
2 LED chip
3 driver IC
4 white glue
5 steel mesh
51 first through hole
52 second through hole
53 boss
6 optical component

### DETAILED DESCRIPTION

Technical solutions in the embodiments of the present application are further described in detail in conjunction with drawings.

In the description of the present application, unless otherwise expressly specified and limited, a term “connected to each other”, “connected”, or “secured” is to be construed in a broad sense, for example, as securely connected, detachably connected, or integrated; mechanically connected or electrically connected; directly connected to each other or indirectly connected to each other via an intermediary; or internally connected between two components or interaction relations between two components. For those of ordinary skill in the art, specific meanings of the preceding terms in the present application may be construed according to specific situations.

In the present application, unless otherwise expressly specified and limited, when a first feature is described as “above” or “below” a second feature, the first feature and the second feature may be in direct contact or be in contact via another feature between the two features instead of being in direct contact. Moreover, when the first feature is “on”, “above”, or “over” the second feature, the first feature is right on, above, or over the second feature, or the first feature is obliquely on, above, or over the second feature, or the first feature is simply at a higher level than the second feature. When the first feature is “under”, “below”, or “underneath” the second feature, the first feature is right under, below, or underneath the second feature, or the first feature is obliquely under, below, or underneath the second feature, or the first feature is simply at a lower level than the second feature.

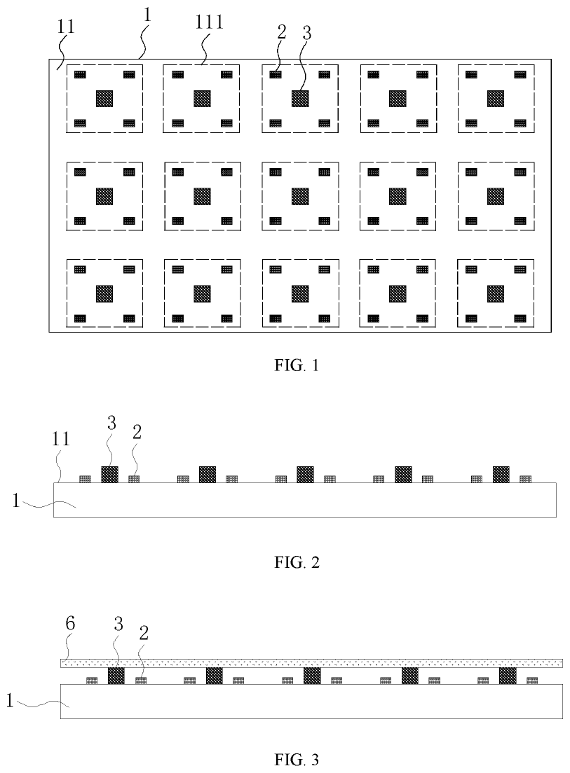

With reference to FIG. 1 to FIG. 3, an embodiment of the present application provides an LED backlight source; the LED backlight source includes a substrate 1, an LED chip 2, and a driver IC 3; the substrate 1 has a first side 11; LED chips 2 and driver ICs 3 are disposed at intervals on the first side 11, respectively; M partitions 111 are disposed on the first side 11, one driver IC 3 and N channels are disposed in each partition 111, and the driver IC 3 controls X LED chips 2 through one channel, where M, N, and X are integers greater than or equal to 1, N is less than or equal to 6, and the appearance of the driver IC 3 is white. For example, the driver IC 3 is discrete, and one driver IC 3 controls multiple LED chips 2 to emit light through one channel. The number of channels N of the driver IC 3 is 1 to 6, and the number of LED chips 2 controlled by each driver IC 3 is small. Through this configuration, the circuit between the driver IC 3 and the LED chips 2 in each partition 111 can be simplified. In addition, when the driver IC 3 needs to be repaired, only a damaged driver IC 3 needs to be separately replaced, and the maintenance costs are low. Moreover, the number of channels of the driver IC 3 is small, which can reduce the volume of the driver IC 3. In this manner, the driver IC 3 and the LED chip 2 can be disposed on the front face of the substrate 1, and the driver IC 3 does not shield the light emission of the LED chip 2. The LED chip 2 and the driver IC 3 are disposed on the first side 11 of the substrate 1, and the driver IC 3 has a white appearance. Thus, the driver IC 3 can not only greatly reduce the absorption of the light emitted by the LED chip 2, but also avoid shadows on the display picture of the display screen. In addition, in the entire backlight module, the driver IC 3 can support another optical component 6 in the backlight module such as a diffusion plate, and thus another support portion does not need to be added to the substrate 1, thereby reducing the manufacturing difficulty of the backlight module, shortening the production cycle of an LED backlight source, and reducing costs.

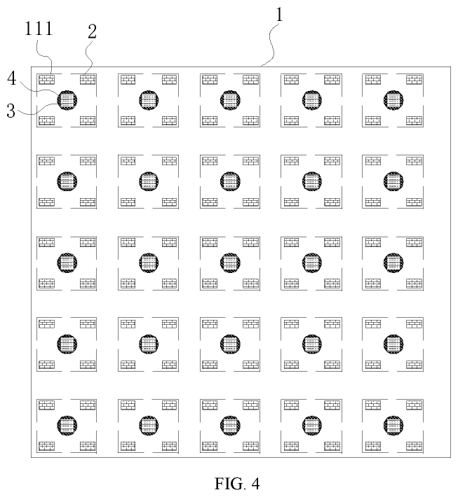

With reference to FIG. 4, in this embodiment, the outer surface of the driver IC 3 is coated with white glue 4. After the LED chip 2 and the driver IC 3 are soldered to the substrate 1, the driver IC 3 with a conventional black housing is coated with white glue 4, and after drying and hardening, the driver IC 3 presents a white appearance.

For example, the white glue 4 is epoxy resin or silicone resin.

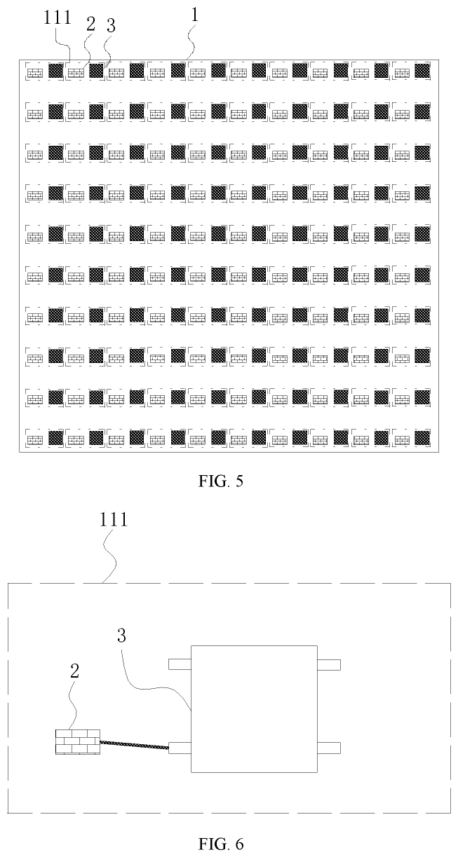

With reference to FIG. 5, in other embodiments, the driver IC 3 is encapsulated by a plastic packaging material, and the plastic packaging material is white plastic. When the driver IC 3 is manufactured, the driver IC 3 is encapsulated by a plastic packaging material so that the driver IC 3 presents a white appearance.

For example, the plastic packaging material includes a whitening agent, the plastic packaging material includes one of epoxy resin, epoxy resin mixture, silicone resin, or polyimide, and the whitening agent may be titanium dioxide.

For example, the center distance between adjacent LED chips 2 is 4 mm to 30 mm.

In this embodiment, the LED chip 2 is an LED flip chip. The LED flip chip has high light extraction efficiency, a good heat dissipation condition, large light extraction power per unit area, high reliability, and low mass manufacturing costs. Moreover, the LED flip chip can be driven by a large current so that the LED chip 2 and the driver IC 3 can be installed on the first side 11 of the substrate 1. In addition, a single-sided aluminum substrate with a low price and a strong heat dissipation capability can be used to replace the traditional substrate 1 of a multi-layer structure, thereby reducing the manufacturing costs of the LED backlight source.

With reference to FIG. 6, an embodiment of the present application provides an LED backlight source; each partition 111 on the substrate 1 of the LED backlight source includes a driver IC 3; the driver IC 3 has four pins, one of which is an output channel; the output channel of the driver IC 3 is connected to an LED chip 2, and one driver IC 3 controls the light emission of an LED chip 2, that is, N=1, and X=1.

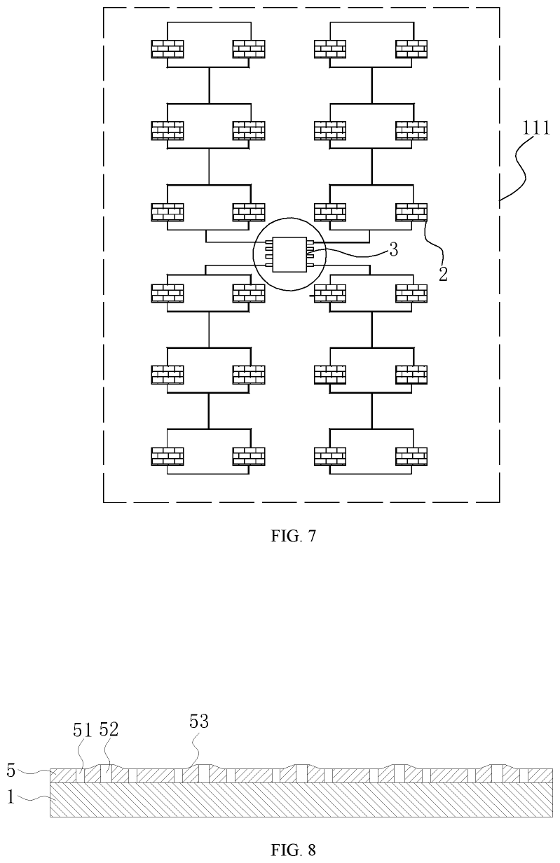

With reference to FIG. 7, another LED backlight source is provided according to this embodiment of the present application; each partition 111 on the substrate 1 of the LED backlight source includes a driver IC 3; the driver IC 3 has eight pins, four of which are output channels; each output channel is connected to six LED chips 2, and the six LED chips 2 may be connected to the output channel in series or in parallel or in mixed connection; one driver IC 3 controls the light emission of twenty-four LED chips 2, that is, N=4, and X=6.

The LED backlight source is not limited to the preceding LED backlight sources. As long as M, N, and X are greater than or equal to 1, and N is less than or equal to 6, a driver IC 3 having a different number of channels and controlling a different number of LED chips 2 may be flexibly configured in an LED backlight source.

With reference to FIG. 8, the present application also provides a manufacturing method for an LED backlight source. The method is used to manufacture an LED backlight source in the embodiments and includes the steps below.

A substrate 1 and a steel mesh 5 are provided, the steel mesh 5 is aligned with the substrate 1, and solder paste is simultaneously applied to an LED pad and an IC pad of the substrate 1 through the steel mesh 5, where the amount of solder paste on the LED pad and the amount of solder paste on the IC pad are different.

An LED chip 2 and a driver IC 3 with a white appearance are provided, and the LED chip 2 and the driver IC 3 are soldered respectively on the LED pad and the IC pad using the reflow soldering to form the LED backlight source.

Before providing the LED chip 2 and the driver IC 3 with the white appearance and soldering the LED chip 2 and the driver IC 3 respectively on the LED pad and the IC pad using the reflow soldering to form the LED backlight source, the driver IC 3 is molded using white plastic to make the appearance of the driver IC 3 white. For example, the white plastic is one of epoxy resin, epoxy resin mixture, silicone resin, or polyimide filled with titanium dioxide as a whitening agent.

After simultaneously applying solder paste to the LED pad and the IC pad of the substrate through the steel mesh, the steel mesh is removed, and the LED chip and driver IC are soldered to the LED pad and IC pad, respectively. That is, the LED backlight source includes the substrate, LED chip, and driver IC, but does not include the steel mesh.

The present application also provides another manufacturing method for an LED backlight source. The method is used to manufacture an LED backlight source in the embodiments and includes the steps below.

A substrate 1 and a steel mesh 5 are provided, the steel mesh 5 is aligned with the substrate 1, and solder paste is simultaneously applied to an LED pad and an IC pad of the substrate 1 through the steel mesh 5, where the amount of solder paste on the LED pad and the amount of solder paste on the IC pad are different.

An LED chip 2 and a driver IC 3 are provided, and the LED chip 2 and the driver IC 3 are soldered respectively on the LED pad and the IC pad using the reflow soldering to form the LED backlight source.

The driver IC 3 is coated with white glue, and the LED backlight source with the driver IC 3 is dried in an oven to make the appearance of the driver IC 3 white. For example, the white glue 4 is epoxy resin or silicone resin containing titanium dioxide as a whitening agent. The method of applying white glue may be dispensing, spraying, or printing.

In this embodiment, multiple first through holes 51 and multiple second through holes 52 are disposed at intervals on the steel mesh 5, the first through holes 51 correspond to the LED pad in position, the second through holes 52 correspond to the IC pad in position, and the depth of the first through hole 51 is less than the depth of the second through hole 52. Since the depth of the first through hole 51 is smaller than the depth of the second through hole 52, the amount of solder paste on the LED pad can be smaller than the amount of solder paste on the IC pad when a scraper evenly adheres the solder paste on the steel mesh 5 to the LED pad and the IC pad through the first through hole 51 and the second through hole 52.

For example, the steel mesh 5 has a first surface and a second surface opposite to each other. The first surface is a flat surface that engages with the first side 11. The second flat surface is a concave and convex surface. Since the size of the LED chip 2 is relatively small, less solder paste is required during soldering, while the size of the driver IC 3 is relatively large, and more solder paste is required during soldering. Steel mesh 5 with different thicknesses is used so that simultaneous coating of solder paste can be achieved using a one-time solder paste printing process and a one-time reflow soldering process, thereby meeting the needs of different solder paste amounts on the LED pad and IC pad and greatly shortening the manufacturing and production cycle of LED backlight sources.

For example, the steel mesh 5 includes a mesh plate, bosses 53 are protruded from a side of the mesh plate away from the substrate 1. Each boss 53 corresponds to a respective second through hole 52, and each second through hole 52 penetrates through a respective boss 53. By the configuration of the boss 53 on the second through hole 52, that is, the second surface of the steel mesh 5 is a concave and convex surface, the depth of the first through hole 51 is less than the depth of the second through hole 52. For example, the height of the boss 53 is equal to the depth of the second through hole 52.

For example, the depth of the first through hole 51 is 0.01 mm to 0.03 mm, and the depth of the second through hole 52 is 0.05 mm to 0.1 mm. By the control of the depths of the first through hole 51 and the second through hole 52, the application of solder paste is facilitated when different depths are met. When the solder paste is applied on the second surface of the steel mesh 5, the scraper can move smoothly on the steel mesh 5 so that the solder paste evenly adheres to the substrate 1.

In the description of the present application, it is to be understood that the orientation or position relationships indicated by terms “above” and the like are the orientation or position relationships shown in the drawings, merely for ease of description and simplifying operations, and these relationships do not indicate or imply that the referred device or component has a specific orientation and is constructed and operated in a specific orientation, and thus it is not to be construed as a limitation to the present application.

In the description of the specification, the description of reference terms “an embodiment” and the like means that specific features, structures, materials or characteristics described in connection with the embodiment are included in at least one embodiment or example of the present application. In the specification, the schematic representation of the preceding terms does not necessarily refer to the same embodiment.

Moreover, it is to be understood that although this specification is described in terms of the embodiments, not each embodiment includes only one independent technical solution. Such description mode of the specification is merely for the sake of clarity, and those skilled in the art should regard the specification as a whole. The technical solutions in the embodiments may also be appropriately combined to form other embodiments which will be understood by those skilled in the art.

1. A light-emitting diode (LED) backlight source, comprising a substrate, at least one LED chip, and at least one driver integrated circuit (IC), wherein the substrate has a first side, the at least one LED chip and the at least one driver IC are disposed at intervals on the first side, M partitions are disposed on the first side, one driver IC and N channels are disposed in each partition, and one driver IC controls X LED chips through one channel, wherein M, N, and X are integers greater than or equal to 1, N is less than or equal to 6, and an appearance of the driver IC is white.

2. The LED backlight source of claim 1, wherein each of at least one driver IC is encapsulated by a plastic packaging material, and the plastic packaging material is white plastic; or
an outer surface of each of the at least one driver IC is coated with white glue.

3. The LED backlight source of claim 2, wherein the driver IC is encapsulated by the plastic packaging material, and the plastic packaging material is the white plastic, the plastic packaging material comprises a whitening agent, and the plastic packaging material comprises one of epoxy resin, epoxy resin mixture, silicone resin, or polyimide.

4. The LED backlight source of claim 2, wherein the outer surface of each of the at least one driver IC is coated with the white glue, the white glue is epoxy resin or silicone resin.

5. The LED backlight source of claim 1, comprising a plurality of LED chips: a center distance between adjacent LED chips is 4 mm to 30 mm.

6. The LED backlight source of claim 1, wherein each of the at least one LED chip is an LED flip chip.

7. A manufacturing method for an LED backlight source, configured to manufacture a LED backlight source comprising a substrate, at least one LED chip and at least one driver integrated circuit (IC), wherein the substrate has a first side, the at least one LED chip and the at least one driver IC are disposed at intervals on the first side. M partitions are disposed on the first side, one driver IC and N channels are disposed in each partition, and one driver IC controls X LED chips through one channel, wherein M, N, and X are integers greater than or equal to 1, N is less than or equal to 6 and an appearance of the driver IC is white;
the manufacturing method for the LED backlight source comprising:
providing a substrate and a steel mesh, aligning the steel mesh with the substrate, and simultaneously applying solder paste to an LED pad and an IC pad of the substrate through the steel mesh, wherein an amount of solder paste on the LED pad and an amount of solder paste on the IC pad are different; and
providing at least one LED chip and at least one driver IC with a white appearance, and soldering the at least one LED chip and the at least one driver IC respectively on the LED pad and the IC pad using reflow soldering to form the LED backlight source.

8. The method of claim 7, wherein a plurality of first through holes and a plurality of second through holes are disposed at intervals on the steel mesh, the plurality of first through holes correspond to the LED pad in position, the plurality of second through holes correspond to the IC pad in position, and a depth of each of the plurality of first through holes is less than a depth of each of the plurality of second through holes.

9. The method of claim 8, wherein the steel mesh comprises a mesh plate, bosses are protruded from a side of the mesh plate away from the substrate, each boss corresponds to a respective second through hole, and each second through hole penetrates through a respective boss.

10. The method of claim 8, wherein the depth of the first through hole is 0.01 mm to 0.03 mm, and the depth of the second through hole is 0.05 mm to 0.1 mm.

11. The method of claim 7, wherein before providing the at least one LED chip and the at least one driver IC with a white appearance and soldering the at least one LED chip and the at least one driver IC respectively on the LED pad and the IC pad using the reflow soldering to form the LED backlight source, further comprising: molding the driver IC using white plastic.

12. A manufacturing method for a light-emitting diode (LED) backlight source, configured to manufacture an LED backlight source comprising a substrate, at least one LED chip, and at least one driver integrated circuit (IC), wherein the substrate has a first side. the at least one LED chip and the at least one driver IC are disposed at intervals on the first side. M partitions are disposed on the first side, one driver IC and N channels are disposed in each partition, and one driver IC controls X LED chips through one channel, wherein M, N, and X are integers greater than or equal to 1, N is less than or equal to 6, and an appearance of the driver IC is white; the manufacturing method for the LED backlight source comprising:
providing a substrate and a steel mesh, aligning the steel mesh with the substrate, and simultaneously applying solder paste to an LED pad and an integrated circuit (IC) pad of the substrate through the steel mesh, wherein an amount of solder paste on the LED pad and an amount of solder paste on the IC pad are different;
providing an LED chip and a driver IC, and soldering the at least one LED chip and the at least one driver IC respectively on the LED pad and the IC pad using reflow soldering to form the LED backlight source; and
coating each of the at least one driver IC with white glue, and drying the LED backlight source with the at least one driver IC in an oven to make the appearance of the driver IC white.

13. The method of claim 7, wherein each of the at least one driver IC is encapsulated by a plastic packaging material, and the plastic packaging material is white plastic.

14. The method of claim 13, wherein the plastic packaging material comprises a whitening agent, and the plastic packaging material comprises one of epoxy resin, epoxy resin mixture, silicone resin, or polyimide.

15. The method of claim 7, wherein the LED backlight source comprises a plurality of LED chips; a center distance between adjacent LED chips is 4 mm to 30 mm.

16. The method of claim 7, wherein each of the at least one LED chip is an LED flip chip.

17. The method of claim 12, wherein the white glue is epoxy resin or silicone resin.

18. The method of claim 12, wherein the LED backlight source comprises a plurality of LED chips; a center distance between adjacent LED chips is 4 mm to 30 mm.

19. The method of claim 12, wherein each of the at least one LED chip is an LED flip chip.

20. The method of claim 9, wherein the depth of the first through hole is 0.01 mm to 0.03 mm, and the depth of the second through hole is 0.05 mm to 0.1 mm.
